(19) United States
(12) Patent Application Publication
(10) Pub. No.: US 2005/0221199 A1
(43) Pub. Date: Oct. 6, 2005

(54) Mask blank and a method for producing the same

(75) Inventor: Torbjorn Sandstrom, Pixbo (SE)

Correspondence Address: HAYNES BEFFEL & WOLFELD LLP, P O BOX 366, HALF MOON BAY, CA, 94019, US

(73) Assignee: Micronic Laser Systems AB, Taby (SE)

(21) Appl. No.: 10/510,059

(22) PCT Filed: Apr. 1, 2003
(86) PCT No.: PCT/SE03/00519

§ 371 Date: May 31, 2005

(30) Foreign Application Priority Data
Apr. 4, 2002 (SE) 0201019-7

(51) Int. Cl. B32B 17/06; B32B 9/00; G03C 5/00; G21K 5/00; G03F 9/00; B32B 15/00

(52) U.S. Cl. 430/5; 428/428; 428/432; 430/322; 378/35

(57) ABSTRACT

An aspect of the present invention includes a method for manufacturing a mask blank. A substrate is provided. A masking layer is formed on said substrate. At least one layer of material is formed on said substrate such that a reflectivity of a writing wavelength to a film sensitive to the writing wavelength is below 4%. Other aspects of the present invention are reflected in the detailed description, figures and claims.

### FIELD OF THE INVENTION

The present invention relates to a method for producing substrates, in particular it relates to a method for producing mask blanks or reticle blanks using said substrate. The invention also relates to a mask substrate and a reticle substrate.

### BACKGROUND OF THE INVENTION

The problems that are solved by the invention are related to the difficulty of making sufficiently accurate and highly resolved masks. In particular it relates to the use of chemically amplified resist. Such chemically amplified resist (CAR) is used for mask making with DUV radiation (Micronic SIGMA 7100 at 248 nm and ETEC ALTA 4000 at 257 nm) and with electron beams (several suppliers). It has also been used for laser pattern generators at 364 nm (study published by DNP). The chemically amplified resist is used for several reasons: high sensitivity, high contrast and high transparency at short wavelengths.

Common problems related to CAR is its sensitivity to various delay times, from post-apply bake (PAB) to exposure, during exposure if the exposure is prolonged, as it may be in a mask pattern generator, and between exposure and post-exposure bake (PEB). Before PAB and after PEB it is generally regarded as stable. The sensitivity to variations in and extension of these delay times, causing changes in edge profiles and CD measures, is partly due to intrinsic and spontaneous reactions in the resist, partly to contamination from the ambient, and partly by reactions with other materials used in the mask blank, in particular the chrome itself.

FIG. 1 shows a mask blank according to prior art. It has a substrate 101, usually quarts, but in reflecting EUV masks it can be any stable material, e.g. silicon or ultra-low expansion (ULE) glass or ceramic. The chrome 102 is covered with a partially anti-reflective layer 103 of, typically, chromium oxide or chromium nitride. The chromium is sputtered onto the quartz substrate and the AR coating is sputtered on top of it, forming a combined film with typically 70-100 nm thickness. The resist 104 is coated on top of the AR layers 103. Contamination from the ambient may be in the form of amines, ammonia or other nitrogen-containing compounds in ppb concentrations. The process is also affected by oxygen and water in the atmosphere, but to a lesser degree, and different for different types of resist chemistries.

Moving to smaller dimensions one would want to use a thinner resist in order to avoid depth-of-focus loss and resist image collapse for small features with high aspect ratio. This has been addressed in another patent application, U.S. Ser. No. 09/664,288, by the same inventor and included herein by reference. The companion application discloses a multi-layer pattern-transfer method to produce masks and similar products with extremely small features. This is likely to be used for reticles written with 157 nm light and with EUV. In a closer future a single-layer chemically amplified process with high stability and good line-width control is desirable. Such a process is described in the following.

It has been found that chemically amplified resists give less than perfect results when used on mask substrates, FIG. 2. The reflectance of the chrome gives standing waves, depicted in FIG. 2 by the plurality of cavities 201 in the resist profile, and the chemical activity of the chrome oxide surface gives a foot 202 in the resist profile. Especially the foot is troublesome as a clean vertical sidewall is needed for good dimension control.

### SUMMARY OF THE INVENTION

Accordingly, it is an object of the present invention to provide a method of preparing a mask blank and a mask blank as such, which overcomes or at least reduces the above-mentioned problems.

This object, among others, is according to a first aspect of the invention attained by a method for manufacturing a mask blank comprising providing a substrate; forming a masking layer on said substrate; forming at least one layer of material on said substrate such that a reflectivity of a writing wavelength to a film sensitive to the writing wavelength is below 4%.

In another embodiment according to the invention, said reflectivity is below 2%.

In another embodiment according to the invention, said reflectivity is below 1%.

In another embodiment according to the invention, said reflectivity is below 0.5%.

In another embodiment according to the invention, a silicon compound is facing the film sensitive to the writing wavelength.

In another embodiment according to the invention a layer of silicon dioxide is facing the film sensitive to the writing wavelength.

In another embodiment according to the invention, the masking material comprises silicon.

In another embodiment according to the invention, said film sensitive to the writing wavelength is less than 300 nm thick.

In another embodiment according to the invention, said film sensitive to the writing wavelength is less than 200 nm thick.

In another embodiment according to the invention, said at least one layer of material comprises oxynitride.

In another embodiment said invention further comprising the actions of exposing at least a portion of said film sensitive to the writing wavelength with a writing wavelength and etching the exposed mask blank in a gas mixture comprising chlorine or fluorine.

In another embodiment according to the invention, the film sensitive to the writing wavelength is having low activation energy.

In another embodiment according tot the invention, the film sensitive to the writing wavelength is a chemically amplified resist (CAR).

In another said invention further comprising the actions of xposing at least a portion of said film sensitive to the writing wavelength with a writing wavelength and stopping the reaction in said film sensitive to the writing wavelength by exposure to a base.

In another embodiment said invention further comprising the action of slowing down a reaction caused by exposure by having an ambient gas of low humidity.

In another embodiment said invention further comprising the action of forming a film of adhesive promoter.

The invention also relates to a method for manufacturing a mask blank comprising the actions of providing a substrate; forming a masking layer on said substrate and forming at least one layer of material on said substrate such that a surface facing a film sensitive to a writing wavelength is chemically inert.

In another embodiment according to the invention, a reflectivity of said writing wavelength to said film sensitive to the writing wavelength is below 4%.

In another embodiment according to the invention, said reflectivity is below 2%.

In another embodiment according to the invention, said reflectivity is below 1%.

In another embodiment according to the invention, said reflectivity is below 0.5%.

In another embodiment according to the invention, a silicon compound is facing the film sensitive to the writing wavelength.

In another embodiment according to the invention, a layer of silicon dioxide is facing the film sensitive to the writing wavelength.

In another embodiment according to the invention, the masking material comprises silicon.

In another embodiment according to the invention, said film sensitive to the writing wavelength is less than 300 nm thick.

In another embodiment according to the invention, said film sensitive to the writing wavelength is less than 200 nm thick.

In another embodiment according to the invention, at least one layer of material comprises oxynitride.

In another embodiment said invention further comprising the action of exposing at least a portion of said film sensitive to the writing wavelength with a writing wavelength and etching the exposed mask blank in a gas mixture comprising chlorine or fluorine.

In another embodiment according to the invention, the film sensitive to the writing wavelength is having low activation energy.

In another embodiment according to the invention, the film sensitive to the writing wavelength is a chemically amplified resist (CAR).

In another embodiment said invention further comprising the actions of exposing at least a portion of said film sensitive to the writing wavelength with a writing wavelength and stopping the reaction in said film sensitive to the writing wavelength by exposure to a base.

In another embodiment said invention further comprising the action of slowing down a reaction caused by exposure by having an ambient gas of low humidity.

The invention also relates to a mask blank comprising a substrate; a masking layer on said substrate and at least one layer of material on said substrate such that a reflectivity of a writing wavelength to a film sensitive to the writing wavelength is below 4%.

In another embodiment of the invention, said reflectivity is below 2%.

In another embodiment of the invention, said reflectivity is below 1%.

In another embodiment according to the invention said reflectivity is below 0.5%.

In another embodiment according to the invention, a silicon compound is facing the film sensitive to the writing wavelength.

In another embodiment according to the invention, a layer of silicon dioxide is facing the film sensitive to the writing wavelength.

In another embodiment according to the invention, the masking material comprises silicon.

In another embodiment according to the invention, said film sensitive to the writing wavelength is less than 300 nm thick.

In another embodiment according to the invention, said film sensitive to the writing wavelength is less than 200 nm thick.

In another embodiment according to the invention, said at least one layer of material comprises oxynitride.

In another embodiment according to the invention, the film sensitive to the writing wavelength is having low activation energy.

In another embodiment according to the invention, the film sensitive to the writing wavelength is a chemically amplified resist (CAR).

In another embodiment said invention further comprising a film of adhesive promoter.

The invention also relates to a mask blank comprising a substrate; a masking layer on said substrate and at least one layer of material on said substrate such that a surface facing a film sensitive to a writing wavelength is chemically inert.

In another embodiment of the invention, a reflectivity of said writing wavelength to said film sensitive to the writing wavelength is below 4%.

In another embodiment according to the invention, said reflectivity is below 2%.

In another embodiment according to the invention, said reflectivity is below 1%.

In another embodiment according to the invention, said reflectivity is below 0.5%.

In another embodiment according to the invention, a silicon compound is facing the film sensitive to the writing wavelength.

In another embodiment according to the invention, a layer of silicon dioxide is facing the film sensitive to the writing wavelength.

In another embodiment according to the invention, the masking material comprises silicon.

In another embodiment according to the invention, said film sensitive to the writing wavelength is less than 300 nm thick.

In another embodiment according to the invention, said film sensitive to the writing wavelength is less than 200 nm thick.

In another embodiment according to the invention, said at least one layer of material comprises oxynitride.

In another embodiment according to the invention, the film sensitive to the writing wavelength is having low activation energy.

In another embodiment according to the invention the film sensitive to the writing wavelength is a chemically amplified resist (CAR).

In another embodiment said invention further comprising a film of adhesive promoter.

Further characteristics of the invention, and advantages thereof, will be evident from the detailed description of preferred embodiments of the present invention given hereinafter and the accompanying FIGS. 1-7, which are given by way of illustration only, and thus are not limitative of the present invention.

### BRIEF DESCRIPTION OF THE DRAWINGS

FIG. 1 shows a photo-mask blank as known in the art with a quartz substrate, a coating consisting of layers of Cr, CrOₓN_{y}, and a resist.

FIG. 2 shows a typical resist profile as known in the art.

FIG. 3 shows an embodiment of the invention with a quartz substrate, a coating comprising Cr, an anti-reflecting coating, a chemically inert top layer, and a resist.

FIG. 4 shows a typical resist profile produced by the invention.

FIG. 5 shows the diffusion of acid as encountered in the current art.

FIG. 6 shows the diffusion of acid when using the inventive substrate/mask blank.

FIG. 7 shows a method for production of a mask blank.

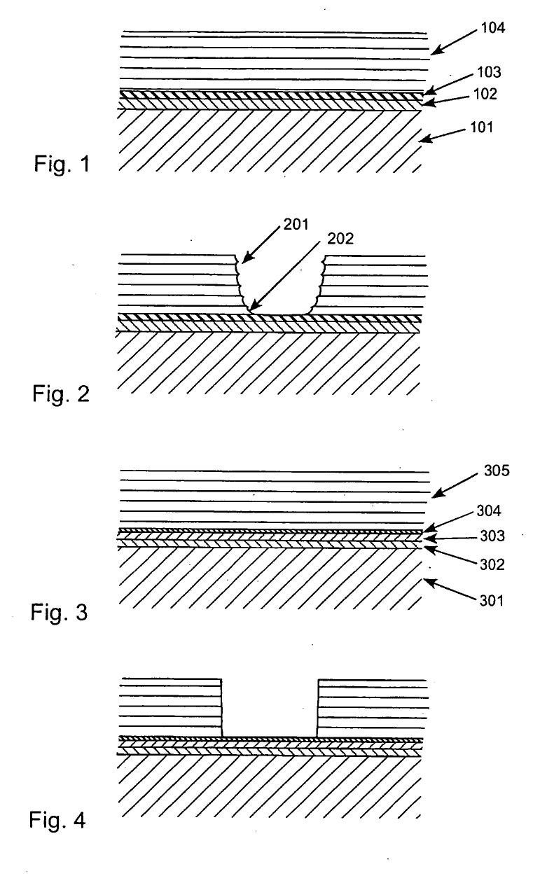

### DETAILED DESCRIPTION

The following detailed description is made with reference to the figures. Preferred embodiments are described to illustrate the present invention, not to limit its scope, which is defined by the claims. Those of ordinary skill in the art will recognize a variety of equivalent variations on the description that follows.

The invention discloses an improved mask substrate with an improved anti-reflective coating having less chemical activity and/or better anti-reflective properties.

An embodiment of the invention is shown in FIG. 3. The depicted embodiment has a substrate 301 and a mask layer 302, typically chrome, an anti-reflecting layer 303 and a chemically inert top layer 304 and a resist layer 305. The anti reflecting layer 303 and the chemically inert layer 304 may comprise one or a plurality of stacked layers. The top surface layer is devoid of chromium and comprises of a chemically inert material, e.g. silicon dioxide or silicon oxynitride. The stack of layers is optimized to give low reflectivity between the resist and the coating. When the resist is removed the reflectivity in air is approximately 6%. The low reflectivity between the stack and the resist removes the standing waves that are formed in current art.

Current mask blanks have a reflectivity of 6% or more between the resist and the chrome stack, giving a periodic modulation of the local exposure dose of 2:1. A post-exposure bake is used to remove the standing waves. This post-exposure is a critical process step and has to be controlled tightly in order not to introduce errors. The diffusion necessary to remove the standing waves does also affect process latitude in a negative way, especially for small features.

Within the general definition of the invention there are many possible configurations, which can be explored and optimized using commercial thin-film programs, e.g., the essential MacLeud. Experimental data for the materials and verification of the design can be obtained from measurements by ellipsometers (e.g. Sopra, Plasmos, Woolam) or reflectometers (Nanometrics, Perkin Elmers, BioRad, n&k).

FIG. 4 depicts the resist profile using the inventive substrate/mask blank

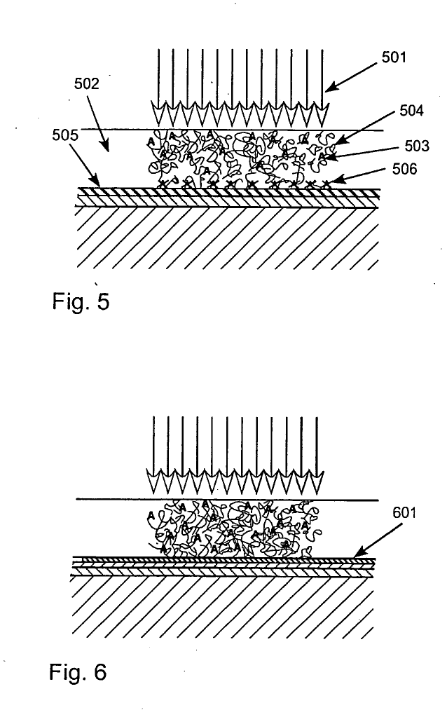

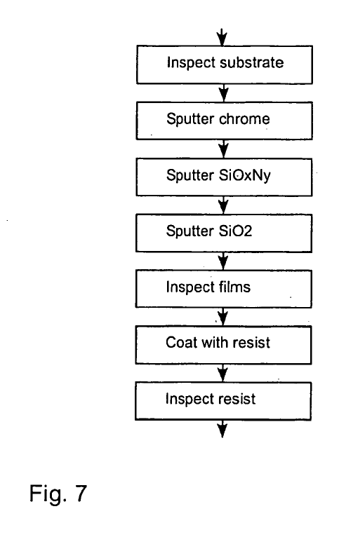

FIG. 5 shows a mechanism behind the resist profile in FIG. 2. The exposing light 501 impinges on the resist 502 and creates acid 503. Partly spontaneously at room temperature and partly during post-exposure baking the acid molecules diffuse along random-walk paths 504 and activates (“de-protects”) the chemically amplified resist so that it becomes soluble in the developer. The effect on the resist is proportional to the length of the diffusing paths. However, when an acid molecule touches the chromium oxide surface 505 it is either neutralized or just bound there 506 so that it does not continue to diffuse. The binding energy can be fairly small and still impede the free diffusion of the acid. The result is a depletion of acid described by an inverse diffusion gradient.

FIG. 6 shows the same diffusion in the invention. The chemically inert top layer does not bind the acid and there is no depletion of acid. Therefore there is no foot.

The production of inventive mask blanks is similar to that currently used, but the exact recipe is different. The chrome and the anti-reflecting film stack are deposited by sputtering. A thin layer of SiO₂ is sputtered on top of the anti-reflecting film. The blank is treated with an adhesive promoter, e.g. HMDS, and the resist is spun on. The blank is then baked to drive out solvents and compact the resist film, inspected and shipped/stored until it is exposed.

Photo-masks have an optical density around 3 or at least above 2.5. Optical density is the logarithm of base 10 of the attenuation in transmission and optical density 3 means 0.001 transmission.

The following is a recipe that gives the desired result with a stack being 90 nm thick. The reflection between the resist and the coating is 0.8% and the optical density is 3.3.

| | | | |
|---|---|---|---|
| Cr | 0.85 - j 2.01, | thickness | 68 nm, |
| SiOₓN_{y} | 2.12 - j 0.50, | thickness | 22 nm, where j is the |
| | | | imaginary part of the |
| | | | complex refractive index. |

The following recipe has a top layer of stoechiometric SiO₂ to further improve the chemical inertness and reflectivity. It has a reflection of 0.3% and an optical density of 2.8.

| Cr | 0.85 - j 2.01, | thickness | 55 nm |
|---|---|---|---|
| SiOₓN_{y} | 2.12 - j 0.50, | thickness | 22 nm |
| SiO₂ | 1.50, | thickness | 10 nm |

A more oxidized surface layer can be obtained in the first recipe by treating the SiOxNy surface with an oxygen plasma.

Another recipe, which is closer to the currently used CrOₓN_{y}, has a reflectivity of 0.6% and an optical density of 3.0.

| Cr | 0.85 - j 2.01, | thickness | 60 nm |
|---|---|---|---|
| CrOₓN_{y} | 2.12 - j 0.80, | thickness | 20 nm |
| SiO₂ | 1.50, | thickness | 10 nm |

Both CrOₓN_{y} and SiOₓN_{y} can be made with varying properties and in the particular case the thickness and/or process parameters must be optimized empirically. The embodiments above are computed based on refractive indices found in the public domain. It is also possible to use other chemically inert compounds to create a chrome-free surface with good properties. Using silicon compounds does have a number of benefits, though. The silicon surface chemistry is well known and adhesion promoters and other surface modifiers are well known and understood. Several processes for producing films of SiO₂ and SiOₓN_{y} are available, including evaporation and sputtering, reactive evaporation and sputtering, CVD and plasma deposition. Silicon glasses have very good adhesion to chromium, either to metallic chrome or to chrome oxides.

In a different embodiment the chrome is replace with silicon. Silicon has higher complex refractive index at 248 nm than Cr, therefore the stack is thinner than for Cr. Furthermore Si is easier to etch and has better dry etch selectivity vs. resist, giving a more stable process and the possibility to use thinner resist. The following stack has 0.0% reflection and 2,7 optical density.

| Si | 1.69 - j 2.76, | thickness | 40 nm |
|---|---|---|---|
| CrOₓN_{y} | 2.12 - j 0.80, | thickness | 27 nm |
| SiO₂ | 1.50, | thickness | 10 nm |

The same materials will work for 193 nm, although the optimum thickness for the different layers may be slightly different.

The issue with the delay times in a mask-writer is that they are long and to some degree unpredictable. Optical pattern generators have a writing time that is proportional to the covered area, but at some complexity level the system has to stop and wait for data, giving some unpredictability to the process.

For long writing times it is advantageous to use a low-activation energy resist, such as for instance a resist named 1100 provided by Clariant or a resist named KRS provided by IBM, where the de-protection of the resist happens spontaneously at room temperature. This is generally accompanied by a diffusion of acid. A final PEB is not necessary for the de-protection but kills any remaining acid and causes diffusion that smoothes out standing waves. With mask blanks according to the present invention there are no or very little standing waves.

The diffusion of acid can be stopped either by the development or by a stopping treatment where the blank is exposed to a high concentration of amines, ammonia or other bases. The simplest stop to the diffusion, however, is to develop the plate. There are several advantages of this: no baking removes one of the larger sources of CD variations, and also one of process bias. The spontaneous de-protection directly after exposure of any point on the surface reduces the influence of long delay times.

Remaining acid causes diffusion and will give a delay-dependant CD error. However, it can be predicted beforehand and pre-compensated. The writing strategy is mentioned in said U.S. application with application Ser. No. 09/664,288 by the same inventor and gives a nearly constant CD effect, which can be corrected for by dose or by manipulation of the data. In said method of exposing a reticle a plurality of exposure passes is used, where said exposure passes are made in a first and a second direction, the first and second directions being essentially opposed.

Some photo resist formulations need water present for the de-protection to take place. This is the reason why chemically amplified resists can be used in electron beam systems with write times of 24 hours or more. Using a dry atmosphere in an optical pattern generator operating in air slows down the de-protection during writing and reduces the delay effect as long as the blank is shielded from water A dry atmosphere causes problems with charging and static electricity, and they must be handled and alleviated, e.g. with ionizers. The writer is purged with dried air. Load locks ensure that there is no ambient air coming into the enclosure.

A silicon-based film etches in plasma with clorine present. This is the same chemistry as for etching chrome so both films can be etched in the same gas mixture. For all-silicon masks the etching can be optimized without regard to the chrome etch requirements.

For optical alignment of a chrome (or equivalent material) pattern to a second layer, it is important that there is a reflectance difference between the resist and the substrate on one side and the resist and the chrome stack on the other. The recipes given above give close to zero reflectivity only for DUV, so a non-actinic sensor will be useful. Inspection can be done at a different wavelength in transmission or reflection, but the low reflectivity can be a problem for inspection in reflection at wavelength.

While the preceding examples are cast in terms of a method, devices and systems employing this method are easily understood. A magnetic memory containing a program capable of practicing the claimed method is one such device. A computer system having memory loaded with a program practicing the claimed method is another such device.

It will be obvious to a person to apply the invention to new situations, such as other wavelengths and materials. Reflecting reticles for EUV is an obvious application. Other masking materials than chrome may be used and the chemical inert layer could be based on other compounds that silicon compounds. An example is to use a diamond-like carbon film.

While the present invention is disclosed by reference to the preferred embodiments and examples detailed above, it is understood that these examples are intended in an illustrative rather than in a limiting sense. It is contemplated that modifications and combinations will readily occur to those skilled in the art, which modifications and combinations will be within the spirit of the invention and the scope of the following claims.

1. A method for manufacturing a mask blank comprising the actions of:
providing a substrate;
forming a masking layer on said substrate;
forming at least one layer of material on said substrate such that a reflectivity of a writing wavelength back into a film sensitive to the writing wavelength is below 4%.

2. The method according to claim 1, wherein said reflectivity is below 2%.

3. The method according to claim 1, wherein said reflectivity is below 1%.

4. The method according to claim 1, wherein said reflectivity is below 0.5%.

5. The method according to claim 1, wherein a silicon compound is facing the film sensitive to the writing wavelength.

6. The method according to claim 1, wherein a layer of silicon dioxide is facing the film sensitive to the writing wavelength.

7. The method according to claim 1, wherein the masking material comprises silicon.

8. The method according to claim 1, wherein said film sensitive to the writing wavelength is less than 300 nm thick.

9. The method according to claim 1, wherein said film sensitive to the writing wavelength is less than 200 nm thick.

10. The method according to claim 1, wherein said at least one layer of material comprises oxynitride.

11. The method according to claim 1, further comprising the action of:
exposing at least a portion of said film sensitive to the writing wavelength with a writing wavelength,
etching the exposed mask blank in a gas mixture comprising chlorine.

12. The method according to claim 1, further comprising the action of:
exposing at least a portion of said film sensitive to the writing wavelength with a writing wavelength,
etching the exposed mask blank in a gas mixture comprising fluorine.

13. The method according to claim 12, wherein the film sensitive to the writing wavelength is having low activation energy.

14. The method according to claim 1, wherein the film sensitive to the writing wavelength is a chemically amplified resist (CAR).

15. The method according to claim 1, further comprising the actions of:
Exposing at least a portion of said film sensitive to the writing wavelength with a writing wavelength,
stopping the reaction in said film sensitive to the writing wavelength by exposure to a base.

16. The method according to claim 12 or 15, further comprising the action of;
slowing down a reaction caused by exposure by having an ambient gas of low humidity.

17. The method according to claim 1, further comprising the action of;
forming a film of adhesive promoter.

18. A method for manufacturing a mask blank comprising the actions of:
providing a substrate;
forming a masking layer on said substrate;
forming at least one layer of material on said substrate such that a surface facing a film sensitive to a writing wavelength is chemically inert.

19. The method according to claim 18, wherein a reflectivity of said writing wavelength back into said film sensitive to the writing wavelength is below 4%.

20. The method according to claim 18, wherein said reflectivity is below 2%.

21. The method according to claim 18, wherein said reflectivity is below 1%.

22. The method according to claim 18, wherein said reflectivity is below 0.5%.

23. The method according to claim 18, wherein a silicon compound is facing the film sensitive to the writing wavelength.

24. The method according to claim 18, wherein a layer of silicon dioxide is facing the film sensitive to the writing wavelength.

25. The method according to claim 18, wherein the masking material comprises silicon.

26. The method according to claim 18, wherein said film sensitive to the writing wavelength is less than 300 nm thick.

27. The method according to claim 18, wherein said film sensitive to the writing wavelength is less than 200 nm thick.

28. The method according to claim 18, wherein at least one layer of material comprises oxynitride.

29. The method according to claim 18, further comprising the action of:
Exposing at least a portion of said film sensitive to the writing wavelength with a writing wavelength,
etching the exposed mask blank in a gas mixture comprising chlorine.

30. The method according to claim 18, further comprising the action of:
exposing at least a portion of said film sensitive to the writing wavelength with a writing wavelength,
etching the exposed mask blank in a gas mixture comprising fluorine.

31. The method according to claim 29, wherein the film sensitive to the writing wavelength is having low activation energy.

32. The method according to claim 18, wherein the film sensitive to the writing wavelength is a chemically amplified resist (CAR).

33. The method according to claim 32, further comprising the actions of:
exposing at least a portion of said film sensitive to the writing wavelength with a writing wavelength,
stopping the reaction in said film sensitive to the writing wavelength by exposure to a base.

34. The method according to claim 29 or 32, further comprising the action of;
slowing down a reaction caused by exposure by having an ambient gas of low humidity.

35. A mask blank comprising
a substrate;
a masking layer on said substrate;
at least one layer of material on said substrate such that a reflectivity of a writing wavelength back into a film sensitive to the writing wavelength is below 4%.

36. The mask blank according to claim 35, wherein said reflectivity is below 2%.

37. The mask blank according to claim 35, wherein said reflectivity is below 1%.

38. The mask blank according to claim 35, wherein said reflectivity is below 0.5%.

39. The mask blank according to claim 35, wherein a silicon compound is facing the film sensitive to the writing wavelength.

40. The mask blank according to claim 35, wherein a layer of silicon dioxide is facing the film sensitive to the writing wavelength.

41. The mask blank according to claim 35, wherein the masking material comprises silicon.

42. The mask blank according to claim 35, wherein said film sensitive to the writing wavelength is less than 300 nm thick.

43. The mask blank according to claim 35, wherein said film sensitive to the writing wavelength is less than 200 nm thick.

44. The mask blank according to claim 35, wherein said at least one layer of material comprises oxynitride

45. The mask blank according to claim 35, wherein the film sensitive to the writing wavelength is having low activation energy.

46. The mask blank according to claim 35, wherein the film sensitive to the writing wavelength is a chemically amplified resist (CAR).

47. The mask blank according to claim 35, further comprising;
a film of adhesive promoter.

48. A mask blank comprising
a substrate;
a masking layer on said substrate;
at least one layer of material on said substrate such that a surface facing a film sensitive to a writing wavelength is chemically inert.

49. The mask blank according to claim 48, wherein a reflectivity of said writing wavelength back into said film sensitive to the writing wavelength is below 4%.

50. The mask blank according to claim 48, wherein said reflectivity is below 2%.

51. The mask blank according to claim 48, wherein said reflectivity is below 1%.

52. The mask blank according to claim 48, wherein said reflectivity is below 0.5%.

53. The mask blank according to claim 48, wherein a silicon compound is facing the film sensitive to the writing wavelength.

54. The mask blank according to claim 48, wherein a layer of silicon dioxide is facing the film sensitive to the writing wavelength.

55. The mask blank according to claim 48, wherein the masking material comprises silicon.

56. The mask blank according to claim 48, wherein said film sensitive to the writing wavelength is less than 300 nm thick.

57. The mask blank according to claim 48, wherein said film sensitive to the writing wavelength is less than 200 nm thick.

58. The mask blank according to claim 48, wherein said at least one layer of material comprises oxynitride

59. The mask blank according to claim 48, wherein the film sensitive to the writing wavelength is having low activation energy.

60. The mask blank according to claim 48, wherein the film sensitive to the writing wavelength is a chemically amplified resist (CAR).

61. The mask blank according to claim 48, further comprising; a film of adhesive promoter.
